(19) United States
(12) Patent Application Publication
(10) Pub. No.: US 2015/0040659 A1
(43) Pub. Date: Feb. 12, 2015

(54) CAPACITIVE FLUID LEVEL DETECTION SENSOR

(71) Applicants: Hong Geun YU, (US); YUMIN SYSTEM TECHNOLOGY CO., LTD., Anyang-si (KR)

(72) Inventor: Hong Geun Yu, Suwon (KR)

(73) Assignees: Hong Geun YU, Suwon (KR); YUMIN SYSTEM TECHNOLOGY CO., LTD., Anyang-si (KR)

(21) Appl. No.: 14/381,934

(22) PCT Filed: Feb. 18, 2013
(86) PCT No.: PCT/KR2013/001223

§ 371 Date: Aug. 28, 2014

(30) Foreign Application Priority Data
Feb. 29, 2012 (KR) 10-2012-0020701

(51) Int. Cl. G01F 23/26; G01R 1/04

(52) U.S. Cl. CPC G01F 23/26; G01R 1/0416
USPC 73/290 R

(57) ABSTRACT

The present invention relates to a fluid level detection sensor, and an objective of the present invention is to provide a capacitive fluid level detection sensor, in which an electrode for sensing a fluid level in a capacitive method is formed on a film in a printing method so that the film can be easily attached to and detached from a connector module having a wireless transmission function, and thus a value of a sensed fluid level can be transmitted to a central control office at a remote site, and the film can be used as a disposable item.

### BACKGROUND OF THE INVENTION

1. Field of the Invention

The present invention relates to a fluid level detection sensor, in which an electrode for sensing a fluid level in a capacitive method is formed on a film in a printing method so that the film can be easily attached to and detached from a wireless module, and thus a value of a sensed fluid level can be transmitted to a remote site, and the film can be used as a disposable item.

2. Background of the Related Art

When an intravenous solution is injected using a Ringer solution tube or bottle used at a clinic, the fluid level of the intravenous solution may not be frequently confirmed due to the lengthy injection.

Although a nurse determines an appropriate time according to the amount of the injected solution to confirm the fluid level, this is not accurate, and, furthermore, if the nurse does not remember the time to confirm, the needle may not be removed at an appropriate time.

### SUMMARY OF THE INVENTION

Therefore, the present invention has been made in view of the above problem, and it is an object of the present invention to provide a capacitive fluid level detection sensor, in which an electrode for sensing a fluid level in a capacitive method is formed on a film in a printing method so that the film can be easily attached to and detached from a connector module having a wireless transmission function, and thus a value of a sensed fluid level can be transmitted to a central control office at a remote site, and the film can be used as a disposable item.

To accomplish the above object, according to one aspect of the present invention, there is provided a capacitive fluid level detection sensor including: a sensor film having a pair of electrodes formed on a base film in parallel to each other in a printing method to make a condenser and an adhesive layer on a bottom surface of the base film; and a connection module connected to connection terminals of the sensor film to convert a capacitance value detected by the electrodes into level information and wirelessly transmit the converted level information to a remote site, in which the connector module is configured to include: a receiving groove formed at one side of a housing to receive the connection terminals of the sensor film; a cover provided on the receiving groove and combined with the housing by means of a hinge to cover the receiving groove; connection pins provided inside the cover to pass through and electrically connect to the connection terminals of the sensor film received in the receiving groove; and pin grooves formed on a bottom unit of the receiving groove at positions corresponding to the connection pins, and a battery; a controller electrically connected to the connection pins to convert the detected capacitance value into the level information; and a wireless transmission unit for wirelessly transmitting the level information calculated by the controller to a remote site are embedded inside the housing.

### BRIEF DESCRIPTION OF THE DRAWINGS

FIG. 1 is a view showing an external appearance structure of the present invention.

FIG. 2 is a view showing the structures of electrodes and connection terminals formed on a base film.

FIG. 3 is a view showing the structure of a connector module.

FIG. 4 is a block diagram of a circuit provided in a connector module.

FIG. 5 is a view showing a state of a sensor of the present invention attached on an intravenous solution tube and sensing a fluid level.

DESCRIPTION OF SYMBOLS

| | |
|---|---|
| 100: Sensor film | 110: Base film |
| 111: Electrode | 112: Connection terminal |
| 120: Adhesive layer | |
| 130: Top surface protection layer | |
| 200: Connector module | |
| 210: Housing | 220: Cover |
| 221: Hinge | 222: Connection pin |
| 230: Receiving groove | 231: Bottom unit |
| 232: Pin groove | 240: Controller |
| 250: Wireless transmission unit | 260: Battery |

### DETAILED DESCRIPTION OF THE PREFERRED EMBODIMENT

The present invention configured as described above will be described in detail with reference to the accompanying drawings.

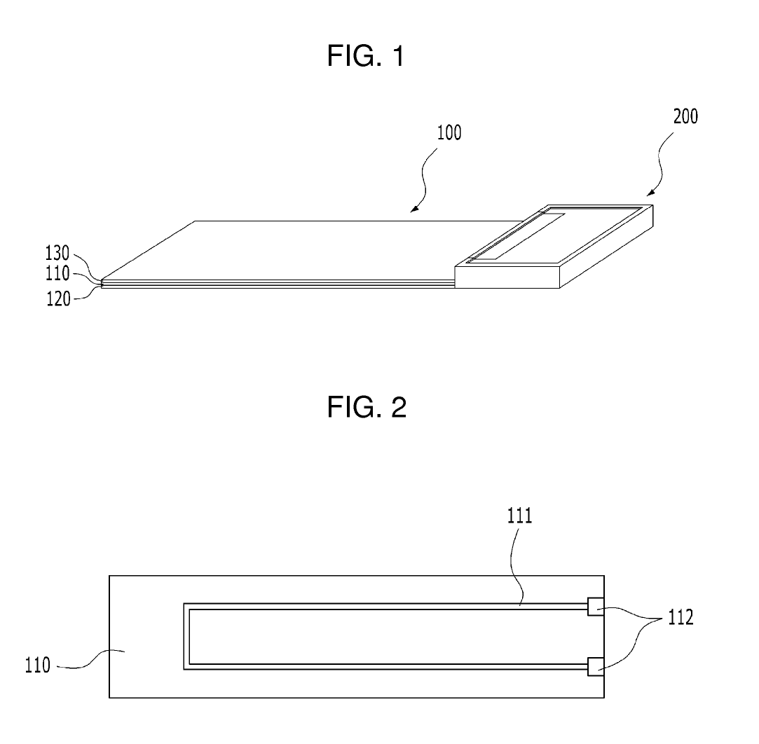

First, as shown in FIG. 1, the present invention is largely configured of a sensor film 100 and a connection module 200.

The sensor film 100 is configured of a base film 110, an adhesive layer 120 formed on the bottom surface of the base film 110, and a top surface protection layer 130 stacked on the top of the base film 110 to protect the top surface of the base film.

Such a base film 110 is formed of a film material such as PET, PE, PTFE, PVC or the like, and a pair of conductor line type electrodes 111 are formed on the top surface of the base film along the length direction in the shape of a strip. The electrodes 111 are formed in a printing method using a silver compound, a pure conductive ink having a resistance of 0 to 20Ω or the like.

The electrodes 111 are electrically connected to connection terminals 112 formed at one end of the base film 110, and end portions of the pair of electrodes 111 are electrically connected to each other to flow current.

The top surface protection layer 130 is stacked on the top of the base film 110 to protect the electrodes 111 and the connection terminals 112 formed on the top surface of the base film 110, and the adhesive layer 120 of a double-sided tape is formed on the bottom surface of the base film 110.

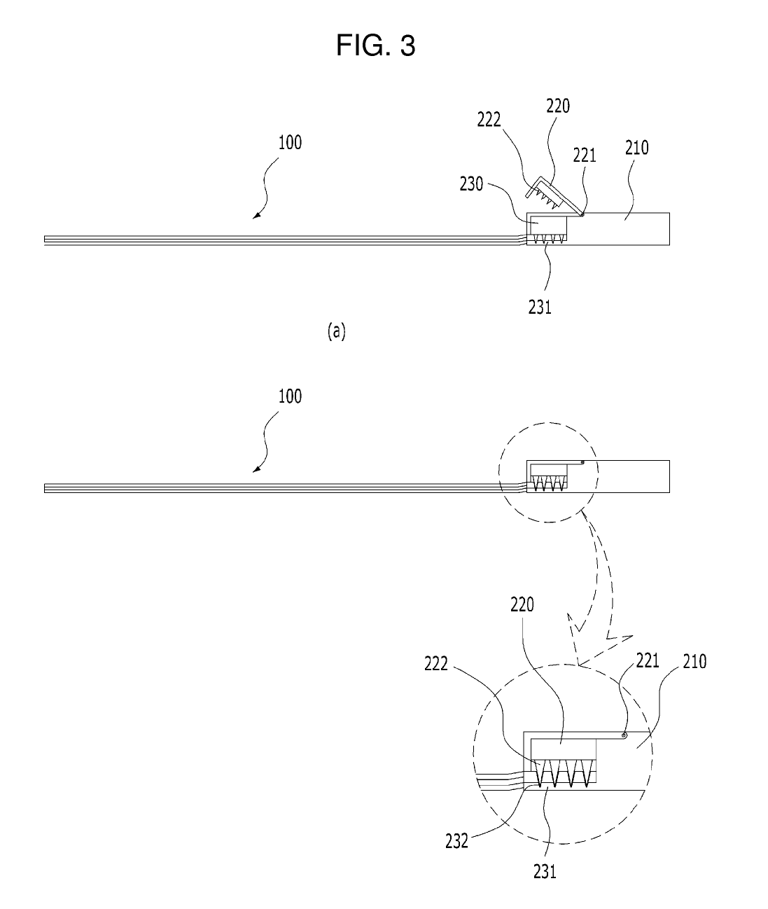

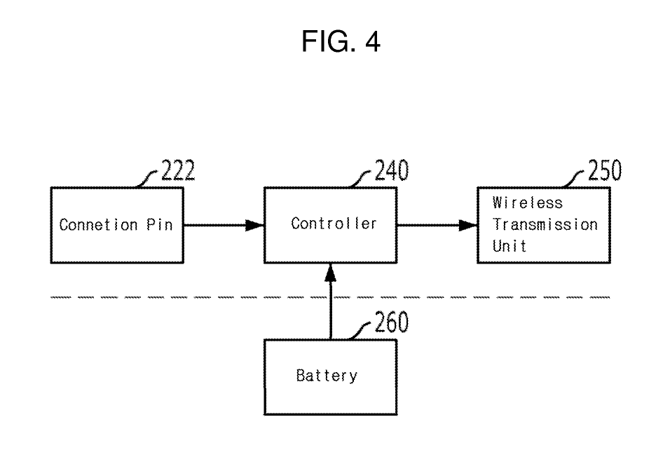

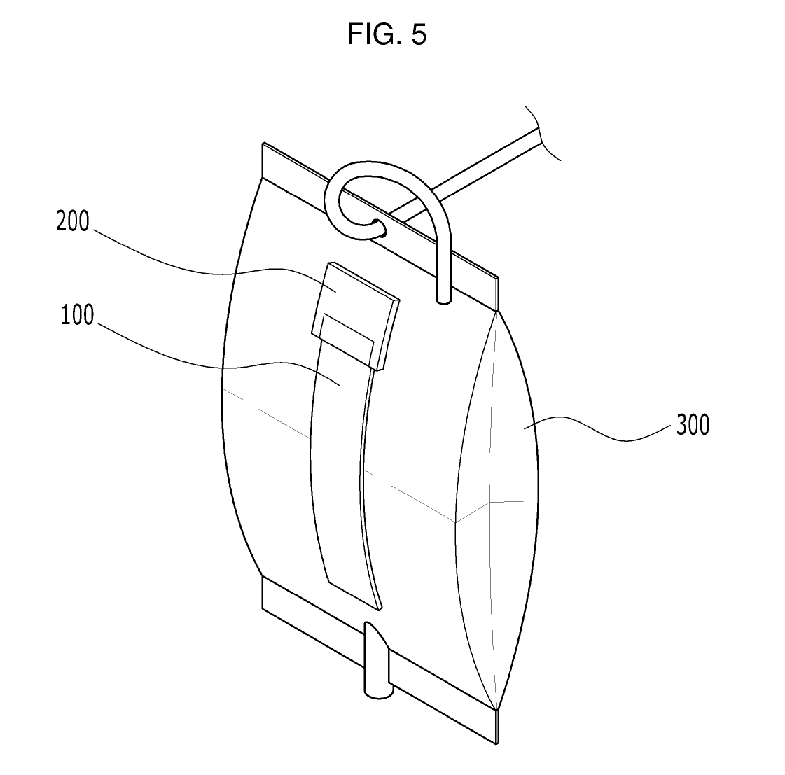

The connector module 200 has a structure of receiving the connection terminals 112 of the base film 110, sensing a fluid level through an electrical connection, and wirelessly transmitting information on a sensed level to a remote site, and as shown in FIG. 3(a), the front side of a housing 210 is open to form a receiving groove 230 for receiving one end of the sensor film 100, and a cover 220 rotating by a hinge 221 is provided on the top of the receiving groove 230.

In addition, conductive connection pins 222 protruded downwards are formed inside the cover 220, and the connection pins 222 are formed to correspond to the positions and the number of connection terminals 112. Pin grooves 232 for inserting the connection pins 222 provided inside the cover 220 are formed on a bottom unit 231 of the receiving groove 230 to correspond to the positions of the connection pins 222.

Therefore, since the receiving groove 230 is covered by the cover 220 while the connection terminals 112 of the base film 110 are received in the receiving groove 230 of the housing 210, the connection pins 222 pass through the connection terminals 112 as shown in FIG. 3(b), and the end portions of the connection pins 222 are received in the pin grooves 232.

Therefore, the connection pins 222 pass through the connection terminals 112 and electrically connect to each other.

In addition, since the connection pins 222 pass through the sensor film 100, the sensor film 100 is prevented from being departed from the connector module 200.

A controller 240 electrically connected to the connection pins 222 to convert a capacitance value sensed by the electrodes 111 into level information, a wireless transmission unit 250 for transmitting a value of the level information output from the controller 240 to a remote site, and a battery 260 are embedded inside the housing 210.

A use state and an operation state of the present invention will be described.

First, if a user opens the cover 220 of the connector module 200, puts an end portion of the sensor film 100 where the connection terminals 112 are formed into the receiving groove 230, and closes the cover 220, the sensor film 100 and the connector module 200 are electrically connected.

Then, the sensor film 100 is attached at a position for sensing a fluid level using the adhesive layer 120, and as shown in FIG. 5, it can be attached on the outer surface of an intravenous solution tube 300 in the form of a pad in the vertical direction.

The controller 240 receives power from the battery 240 provided inside the housing 210, supplies power for periodically sensing a temperature through the connection pins 222, and receives a capacitance value from the electrodes 111.

The capacitance is a unique value of static electricity that every substance has, and if a substance is placed between the two electrodes 111, a capacitance value of the substance is inverse proportional to the distance between the electrodes 111 and proportional to the areas of the electrodes 111.

A fluid level is sensed by detecting an electrical signal value corresponding to such a property.

Therefore, since the capacitance value changes according to the fluid level of the intravenous solution tube 300, the controller 240 reads the changing capacitance value, converts the value into level information, and wirelessly transmits the level information to a central control office at a remote site through the wireless transmission unit 250.

When the sensor film 100 is replaced, the connector module 200 is separated from the fixed sensor film 100 when the cover 220 is opened and the sensor film 100 is removed, and the sensor can be reused by connecting a new sensor film 100 to the separated connection module 200 as described above and attaching the sensor film on the intravenous solution tube 300.

That is, the sensor film 100 can be used as a disposable item, and the connector module 200 can be used repeatedly.

Since the present invention uses a flexible film material as described above, the sensor can be easily attached to a curved intravenous solution tube or bottle, and since the electrodes for sensing capacitance are formed in a printing method, it is easy to manufacture the sensor, and manufacturing cost of the sensor is low.

In addition, since the sensor can be manufactured in various sizes, can be easily attached to and detached from a wireless module, and is able to transmit information on a sensed fluid level to a central control office at a remote site, it is advantageous in that a complex wiring is not needed, and changes of the fluid level can be immediately confirmed at a remote site to properly cope with the changes in the fluid level.

While the present invention has been described with reference to the particular illustrative embodiments, it is not to be restricted by the embodiments but only by the appended claims. It is to be appreciated that those skilled in the art can change or modify the embodiments without departing from the scope and spirit of the present invention.

What is claimed is:

1. A capacitive fluid level detection sensor comprising:
a sensor film having a pair of electrodes formed on a base film in parallel to each other in a printing method to make a condenser and an adhesive layer on a bottom surface of the base film; and
a connection module connected to connection terminals of the sensor film to convert a capacitance value detected by the electrodes into level information and wirelessly transmit the converted level information to a remote site, wherein
the connector module is configured to include:
a receiving groove formed at one side of a housing to receive the connection terminals of the sensor film;
a cover provided on the receiving groove and combined with the housing by means of a hinge to cover the receiving groove;
connection pins provided inside the cover to pass through and electrically connect to the connection terminals of the sensor film received in the receiving groove; and
pin grooves formed on a bottom unit of the receiving groove at positions corresponding to the connection pins, and
a battery;
a controller electrically connected to the connection pins to convert the detected capacitance value into the level information; and
a wireless transmission unit for wirelessly transmitting the level information calculated by the controller to a remote site are embedded inside the housing.
